(19) United States
(12) Patent Application Publication
(10) Pub. No.: US 2024/0254630 A1
(43) Pub. Date: Aug. 1, 2024

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Hideo TATENO, Toyama-shi (JP); Yusaku OKAJIMA, Toyama-shi (JP); Makoto HIRANO, Toyama-shi (JP); Satoshi TAKANO, Toyama-shi (JP)

(73) Assignee: Kokusai Electric Corporation, Tokyo (JP)

(21) Appl. No.: 18/612,425

(22) Filed: Mar. 21, 2024

Related U.S. Application Data
(63) Continuation of application No. PCT/JP21/35191, filed on Sep. 24, 2021.

(51) Int. Cl. C23C 16/48; C23C 16/44; C23C 16/455; H01L 21/02; H01L 21/66

(52) U.S. Cl. CPC C23C 16/481; C23C 16/4412; C23C 16/45557; H01L 21/02255; H01L 22/12; H01L 21/02164; H01L 21/02271

(57) ABSTRACT

A technique including a reaction chamber that accommodates a substrate held by a substrate holder, a heater disposed around the reaction chamber, and an exhauster disposed laterally to the reaction chamber and configured to be capable of accommodating a first temperature measurer disposed extending in a direction parallel to a surface of the substrate held by the substrate holder from the outside of the reaction chamber toward the inside of the reaction chamber.

### CROSS-REFERENCE TO RELATED APPLICATION

This application is a Bypass Continuation Application of PCT International Application No. PCT/JP2021/035191, filed on Sep. 24, 2021, the entire contents of which are incorporated herein by reference.

### BACKGROUND

### Field

The present disclosure relates to a substrate processing apparatus, a method of processing a substrate, a method of manufacturing a semiconductor device, and a recording medium.

### Description of the Related Art

For example, a hot wall type heat treatment apparatus including a process chamber that processes a wafer, a heater that is installed outside the process chamber and heats the process chamber, a thermocouple that measures a temperature of the process chamber, and a controller that performs feedback control of the heater on the basis of temperature measurement of the thermocouple, has been disclosed.

### SUMMARY

In the configuration, a temperature in the vicinity of substrates cannot be accurately measured, and it may be difficult to improve processing uniformity of the substrates.

The present disclosure provides a technique capable of solving the above-described problem in the related art and improving processing uniformity of substrates.

According to an embodiment of the present disclosure, there is provides a technique including:
a reaction chamber that accommodates a substrate held by a substrate holder;
a heater disposed around the reaction chamber; and
an exhauster disposed laterally to the reaction chamber and configured to be capable of accommodating a first temperature measurer disposed extending in a direction parallel to a surface of the substrate held by the substrate holder from an outside of the reaction chamber toward an inside of the reaction chamber.

### BRIEF DESCRIPTION OF THE DRAWINGS

FIG. 1 is a cross-sectional view illustrating a configuration of a main part of a substrate processing apparatus according to a first embodiment of the present disclosure.

FIG. 2 is a cross-sectional view illustrating a configuration of the main part of the substrate processing apparatus according to the first embodiment of the present disclosure in a direction perpendicular to FIG. 1.

FIG. 3 is a cross-sectional view of a gas temperature measurer of the substrate processing apparatus according to the first embodiment of the present disclosure.

FIG. 4 is an enlarged cross-sectional view illustrating details of a portion D in FIG. 3 of the temperature measurer of the substrate processing apparatus according to the first embodiment of the present disclosure.

FIG. 5 is a cross-sectional view illustrating details of an attachment portion of the temperature measurer of the substrate processing apparatus according to the first embodiment of the present disclosure to be attached to a side wall surface of an exhauster.

FIG. 6 is a cross-sectional view illustrating a configuration of a main part in a state where a plurality of temperature measurers installed in the substrate processing apparatus according to the first embodiment of the present disclosure are inserted onto a wafer.

FIG. 7 is a graph indicating a relationship between a horizontal direction and temperatures obtained by measurement by a plurality of temperature measurers installed in the substrate processing apparatus according to the first embodiment of the present disclosure.

FIG. 8 is a graph indicating a temperature distribution in a horizontal direction and a height direction obtained from the relationship between the horizontal direction and the temperatures obtained by measurement by the plurality of temperature measurers installed in the substrate processing apparatus according to the first embodiment of the present disclosure.

FIG. 9 is a block diagram illustrating a configuration of a controller of the substrate processing apparatus according to the first embodiment of the present disclosure.

FIG. 10 is a flowchart indicating processing flow of a substrate processing method according to the first embodiment of the present disclosure.

FIG. 11 is a list indicating items to be controlled by the controller of the substrate processing apparatus according to the first embodiment of the present disclosure.

FIG. 12 is a block diagram illustrating a detailed configuration of a gas supplier of the substrate processing apparatus according to the first embodiment of the present disclosure.

FIG. 13 is a cross-sectional view illustrating a configuration of a main part of a substrate processing apparatus according to a second embodiment of the present disclosure.

### DETAILED DESCRIPTION

In the present disclosure, a temperature distribution inside a substrate processing apparatus is measured in advance, and at the time of substrate processing, a condition of substrate processing is controlled using temperature distribution data measured in advance, so that a plurality of substrates to be processed at the same time can be subjected to homogeneous processing over in-plane of each substrate.

Embodiments of the present disclosure will be described in detail below on the basis of the drawings. In all drawings for describing the embodiments of the present disclosure, components having the same functions are denoted by the same reference signs, and thus duplicate description thereof will be omitted in principle.

Note that the present disclosure should not be construed as being limited to the following embodiments. It is obvious to those skilled in the art that the specific configurations can be modified without departing from the idea or spirit of the present disclosure.

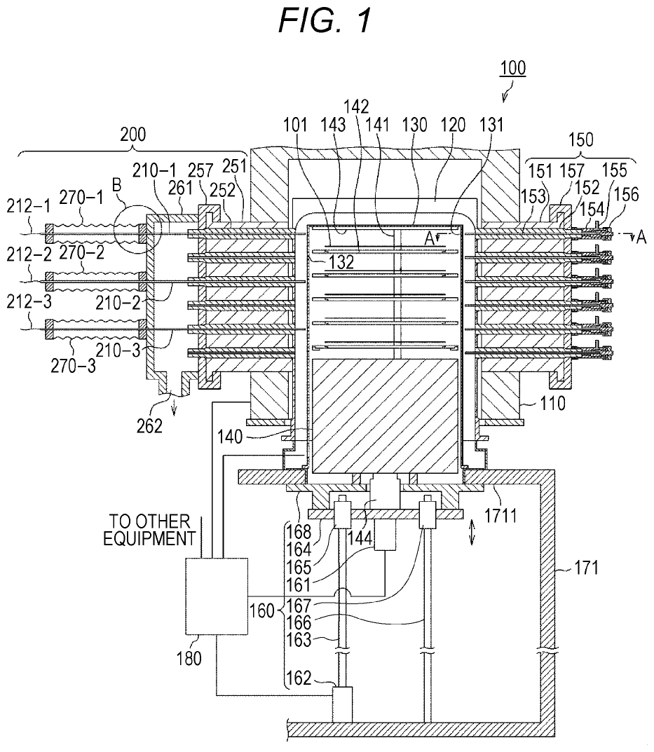

A first embodiment of the present disclosure will be described with reference to FIGS. 1 to 12.

### (Overall Configuration)

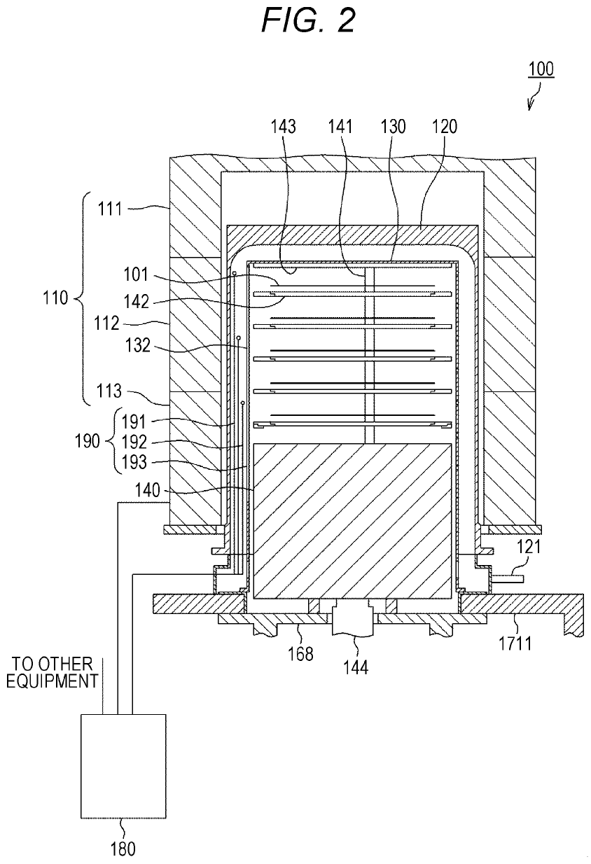

FIG. 1 is a cross-sectional view illustrating a configuration of a main part of a substrate processing apparatus 100 according to the present embodiment, and FIG. 2 is a cross-sectional view illustrating a configuration of the main part in a direction perpendicular to a center of the substrate processing apparatus 100 in FIG. 1.

FIGS. 1 and 2 illustrate a heater 110, a reaction tube (reaction chamber) 120, an inner tube 130, a substrate support (boat) 140, a gas supplier 150 that supplies gas to the inside of the inner tube 130, a boat elevator 160 that takes in and out the substrate support (boat) 140 to and from the inside of the inner tube 130, a first temperature measurer 200, a second temperature measurer 190, and a controller 180 that controls the entire substrate processing apparatus 100.

The heater 110 heats the inside of the inner tube 130 including the reaction tube 120 in a state where the substrate support (boat) 140 is attached to the inside of the inner tube 130 by the boat elevator 160. As illustrated in FIG. 2, the heater 110 may be divided into zone heaters (in the example of FIGS. 1 and 2, three zone heaters of 111, 112 and 113) divided into a plurality of blocks in a vertical direction, and for each zone heater, a voltage to be applied may be adjusted on the basis of data of temperature sensors 191, 192 and 193 of the second temperature measurer 190 described later to control a heating state.

The substrate support (boat) 140 holds a plurality of substrates (wafers) 101 and partitions the plurality of substrates with a plurality of partition plates 142 supported by a partition support 141. A top plate 143 is located at the top of the partition plates 142. A support column 144 of the substrate support 140 is provided.

The substrate support 140 is connected to the boat elevator 160 by the support column 144, and the plurality of held substrates 101 are taken in and out of the inner tube 130 (lower portion of the inner tube 130) by the boat elevator 160.

The gas supplier 150 supplies a gas to the inside of the inner tube 130, and a plurality of gas suppliers are provided in the same plane of the cross section illustrated in FIG. 1 so that the gas can be supplied for each substrate 101 in accordance with a pitch (interval) in the vertical direction of the substrates 101 held by the substrate support 140. The gas supplier 150 is attached in a direction substantially parallel to the surfaces of the substrates 101 held by the substrate support 140 inside the inner tube 130.

A plurality of gas introduction holes 131 are formed in the inner tube 130 at positions facing a distal end portion of the gas supplier 150 so as to introduce the gas supplied from the gas supplier 150 into the inner tube 130.

On the other hand, slits 132 are formed in portions facing portions where the plurality of gas introduction holes 131 are formed in the wall surface of the inner tube 130, and among the gas supplied from the plurality of gas introduction holes 131 to the inside of the inner tube 130, the gas that has not contributed to reaction inside the inner tube 130 including the surfaces of the substrates 101 held by the substrate support 140 is discharged from the inside of the inner tube 130 to the reaction tube 120 side.

The gas discharged from the inside of the inner tube 130 to the reaction tube 120 side through the slits 132 is discharged from an exhauster 261 to outside of the reaction tube 120 through an exhaust port 262 by exhaust means constituted with a vacuum pump (not illustrated), or the like.

The boat elevator 160 takes in and out the substrate support 140 into and from the inner tube 130, that is, takes out the substrate support 140 from the inside of the inner tube 130 to the outside (lower portion of the inner tube 130), or conversely, inserts the substrate support 140 from the outside of the inner tube 130 (lower portion of the inner tube 130) to the inside.

The boat elevator 160 includes a table 164 that supports the support column 144 of the substrate support 140, an upper table 168 mounted on the table 164, a rotary drive motor 161 that is fixed to the table 164 and rotationally drives the support column 144, a vertical drive motor 162 that drives the table 164 in a vertical direction, a ball screw 163 that is connected to the vertical drive motor 162, a ball nut 165 that is fixed to the table 164 and screwed with the ball screw 163, a guide shaft 166 that guides movement of the table 164 in the vertical direction, and a ball bearing 167 that is fixed to the table 164 and receives the movement of the table 164 in the vertical direction along the guide shaft 166.

By driving the vertical drive motor 162 to raise the upper table 168 by the boat elevator 160 until the upper table 168 abuts on an upper surface 1711 of a frame 171, the substrates 101 held by the substrate support 140 are disposed inside the inner tube 130 as illustrated in FIG. 1. In this state, the upper table 168 abuts on the upper surface 1711 of the frame 171 to keep the inside of the reaction tube 120 sealed to the outside, and the inside of the reaction tube 120 can be maintained in a vacuum state by vacuum-exhausting from the exhauster 261 by a vacuum exhauster (vacuum pump) (not illustrated).

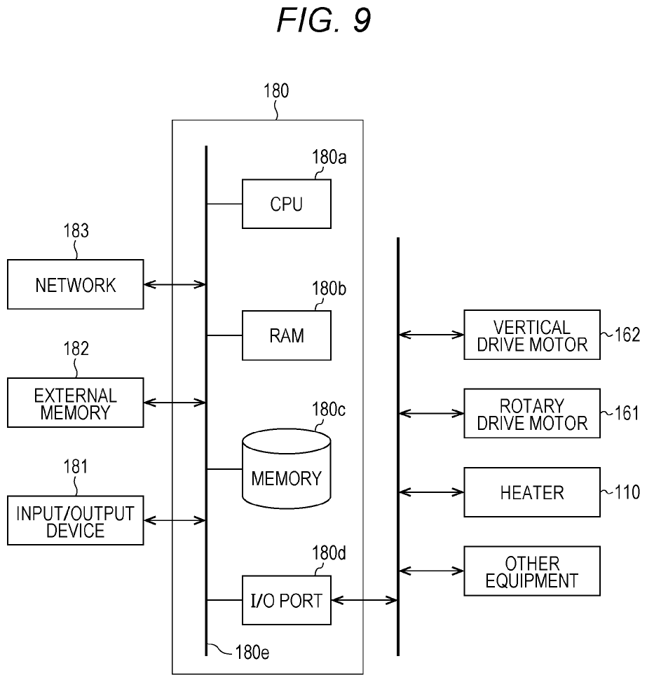

The controller 180 controls operation of each component of the substrate processing apparatus 100. Details of the controller will be described with reference to FIG. 9.

FIG. 2 illustrates the second temperature measurer 190 that measures the temperature of a lateral portion of the inner wall of the reaction tube 120, and temperature sensors 191, 192 and 193 are installed at corresponding positions of the first to third zone heaters 111, 112 and 113, respectively, to measure the temperature inside the reaction tube 120 that is being heated by the heater 110. The first temperature measurer 200 will be described later.

FIG. 12 illustrates a configuration of a gas supply source. The gas supply source is configured to share a valve and an MFC for each gas type and supply the gas from nozzles 330-1 to 330-8 that branch the valve and constitute the nozzle 330 to each of eight gas introduction tubes 155 provided in the gas supplier 150 illustrated in FIG. 1.

In other words, in the present disclosure, a flow rate of the source gas supplied through the gas supplier 150 is controlled by the MFC 321, on/off of the gas supply is controlled by the valve 311, and then the source gas is branched into the nozzles 330-1 to 330-8 and supplied from the respective nozzles to the gas introduction tubes 155 inside the gas supplier 150.

In addition, a flow rate of the reactant gas to be supplied through a gas supply pipe 332 is controlled by the MFC 322, on/off of the gas supply is controlled by the valve 312, and then the gas is branched into the nozzles 330-1 to 330-8 and supplied from the respective nozzles to the gas introduction tubes 155 inside the gas supplier 150.

Further, a flow rate of the carrier gas to be supplied through a gas supply pipe 333 is controlled by the MFC 323, on/off of the gas supply is controlled by the valve 313, and then the gas is branched into the nozzles 330-1 to 330-8 and supplied from the respective nozzles to the gas introduction tubes 155 inside the gas supplier 150.

According to the present disclosure, the valve and the MFC are shared for each gas type, so that a configuration of the gas supply system can be simplified.

In the configuration described in FIG. 1, the first temperature measurer 200 measures the temperature distribution of upper portions of the substrates 101 held by the substrate support 140 inside the inner tube 130.

The first temperature measurer 200 includes a main body portion 251 and a metal protrusion cover 257 respectively having the same structures as a main body portion 151 and a metal protrusion cover 157 of the gas supplier 150 and has a configuration in which tubes 210-1 to 210-3 to which temperature sensors are attached are inserted into guide pipes 252 attached to the main body portion 251. The tubes 210-1 to 210-3 pass through the inside of the exhauster 261 and exit to the outside through bellows 270-1 to 270-3 serving as position adjusters, respectively.

In addition, the first temperature measurer 200 is disposed in a processing space between the substrates 101 and the exhauster 261 by the bellows 270-1 to 270-3 as a position at which the temperatures of the substrates 101 are measured during a substrate processing process (film formation process) to be described later and is configured to measure the vicinity of the substrates 101.

The tubes 210-1 to 210-3 are formed to have a length such that distal end portions pass through the slits 132 formed in the inner tube 130 and reach end portions of the substrates 101 held by the substrate support 140 in the inner tube 130 on the opposite side to the slits 132 in a state of being pushed into the reaction tube 120.

The tubes 210-1 to 210-3 may be individually taken into and out of the reaction tube 120, or the tubes 210-1 to 210-3 may be simultaneously taken into and out of the reaction tube 120 using driving means (driver).

The first temperature measurer 200 includes, for example, two position sensors, one of which detects positions at which the tubes 210-1 to 210-3 reach a retreating end as illustrated in FIG. 1, and the other of which detects positions at which the tubes 210-1 to 210-3 reach an advancing end. Further, each tube may be provided with a plurality of position sensors to detect intermediate positions (temperature measurement positions) of the tubes 210-1 to 210-3.

The tube 210-1 measures a temperature distribution on the substrates 101 held by the substrate support 140 in a region heated by the first zone heater 111 of the heater 110, the tube 210-2 measures a temperature distribution on the substrates 101 held by the substrate support 140 in a region heated by the second zone heater 112 of the heater 110, and the tube 210-3 measures a temperature distribution on the substrates 101 held by the substrate support 140 in a region heated by the third zone heater 113 of the heater 110.

Here, the measurement position in a height direction of the temperature sensor 191 of the second temperature measurer 190 with respect to the inner tube 130 is set at substantially the same height as the height of the tube 210-1, the measurement position in a height direction of the temperature sensor 192 of the second temperature measurer 190 is set at substantially the same height as the height of the tube 210-2, and the measurement position in a height direction of the temperature sensor 193 of the second temperature measurer 190 is set at substantially the same height as the height of the tube 210-3.

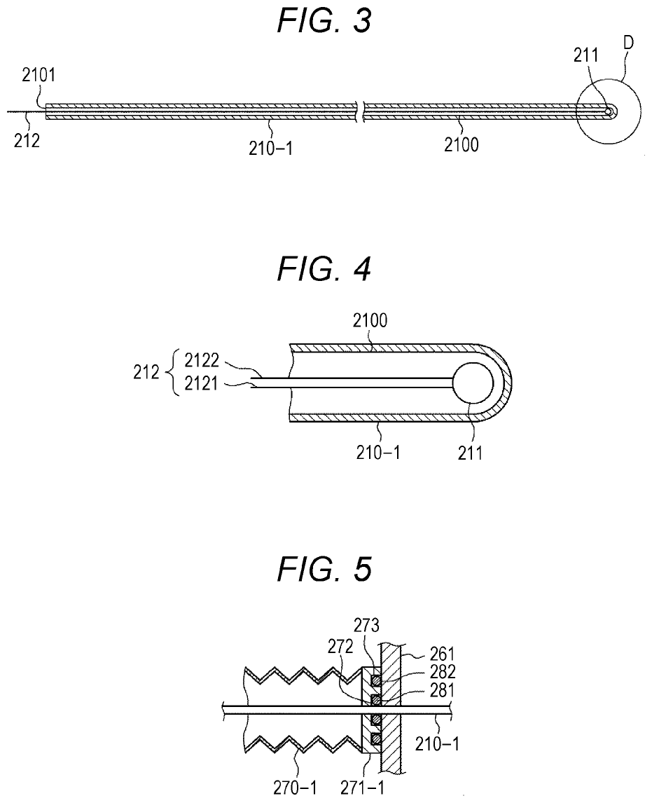

FIG. 3 is a cross-sectional view of a state in which the temperature sensor 211 is attached inside the tube 210-1 of the first temperature measurer 200. The tubes 210-1 and 210-3 also have a similar structure.

FIG. 4 illustrates details of a portion surrounded by a circle D in the distal end portion of the tube 210-1 of the first temperature measurer 200 in FIG. 3. A hole 2100 is formed inside the tube 210-1, but the hole 2100 is closed at the distal end portion of the tube 210-1. On the other hand, as illustrated in FIG. 3, the hole 2100 penetrates the end portion of the tube 210-1 on the opposite side to the distal end portion to form an opening 2101.

The temperature sensor (a thermocouple type temperature sensor in the present embodiment) 211 is inserted into the hole 2100 formed in the tube 210-1 from the side of the opening 2104 and is fixed to the vicinity of the distal end portion of the hole 2100 formed in the tube 210-1. From the temperature sensor 211, electrical wires 2121 and 2122 (hereinafter, these are collectively referred to as an electric wire 212) extend to the outside of the opening 2101 and are connected to the controller 180, and a signal detected by the temperature sensor 211 is sent to the controller 180.

A detailed configuration of a region B circled in FIG. 1, that is, a detailed configuration of the vacuum bellows 270-1 and the tube 210-1 attached to the exhauster 261 is illustrated in FIG. 5. A flange 271 at the end portion of the vacuum bellows 270-1 is provided with a groove 273 to which an O-ring 282 for vacuum sealing with the exhauster 261 is attached, and a groove 272 to which an O-ring 281 for vacuum sealing with the tube 210-1 is attached.

In such a configuration, the O-ring 282 maintains airtightness between the flange 271 and the exhauster 261. On the other hand, the airtightness between the flange 271 and the tube 210-1 is held by the O-ring 281, but the tube 210-1 is freely moved in an axial direction.

With such a configuration, it is possible to adjust a position with respect to the inner tube 130 by moving the tube 210-1 in the axial direction while maintaining vacuum in a state where the inside of the inner tube 130 is vacuum-exhausted from the exhauster 261 through the slits 132 formed in the inner tube 130 by operating the exhaust means including a vacuum pump, or the like (not illustrated).

FIG. 1 illustrates a state in which the tubes 210-1 to 210-3 retreat in the axial direction, and the distal end portions of the tubes 210-1 to 210-3 are detached from the slits 132 of the inner tube 130.

By retreating the tubes 210-1 to 210-3 in the axial direction to be put into a state as illustrated in FIG. 1, it is possible to prevent the tubes 210-1 to 210-3 from interfering with the inner tube 130 when the boat elevator 160 is driven to take the substrate support 140 in and out of the inner tube 130.

Note that FIG. 1 illustrates a state in which the distal end portions of the tubes 210-1 to 210-3 retreat to a position detached from the slits 132 of the inner tube 130. However, it is only necessary that the distal end portions do not interfere with the substrate support 140 to be taken in and out of the inner tube 130, and thus, the distal end portions of the tubes 210-1 to 210-3 may enter the slits 132 without being detached from the slits 132 of the inner tube 130.

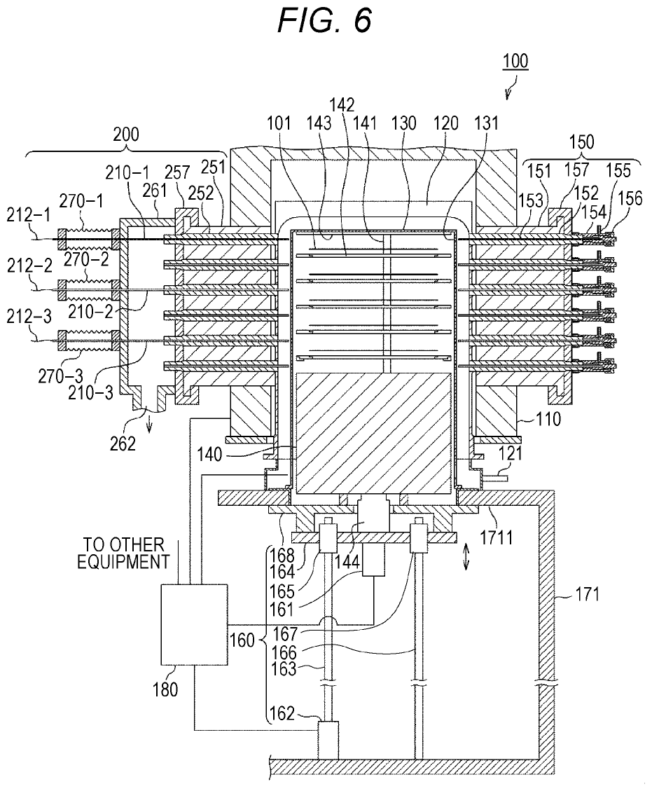

On the other hand, FIG. 6 illustrates a state in which the tubes 210-1 to 210-3 are advanced in the axial direction in a state in which the substrate support 140 is inserted into the inner tube 130 by driving the boat elevator 160. In this state, the distal end portions of the tubes 210-1 to 210-3 are inserted to the end portions of the substrates 101 held by the substrate support 140 on the opposite side to the slits 132.

In a state where the substrates 101 are heated by the heater 110, the temperature distribution of the substrates 101 can be measured by continuously retreating or retreating stepwise the tubes 210-1 to 210-3 from the state of being advanced to the position illustrated in FIG. 6 to the position illustrated in FIG. 1, or by continuously advancing or advancing stepwise the tubes from the position illustrated in FIG. 1 to the position illustrated in FIG. 6.

Although FIGS. 3 and 4 illustrate an example in which only one temperature sensor 211 is mounted inside the hole 2100 formed in the tube 210-1, the temperature sensor 211 may be fixed to a plurality of positions (for example, four positions) at predetermined intervals inside the hole 2100. In this manner, by attaching the plurality of temperature sensors 211 to the inside of the tubes 210-1 to 210-3 at a predetermined pitch, the temperatures at a plurality of positions can be simultaneously measured at the same height inside the inner tube 130 without moving the tubes 210-1 to 210-3.

In the above example, the example in which the temperature sensor 211 is fixed inside the hole 2100 formed in the tube 210-1 has been described. However, instead of inserting and fixing one temperature sensor 211 inside the hole 2100 formed in the tube 210-1, temperatures at a plurality of positions may be measured while moving the temperature sensor 211 by a predetermined pitch inside the hole 2100.

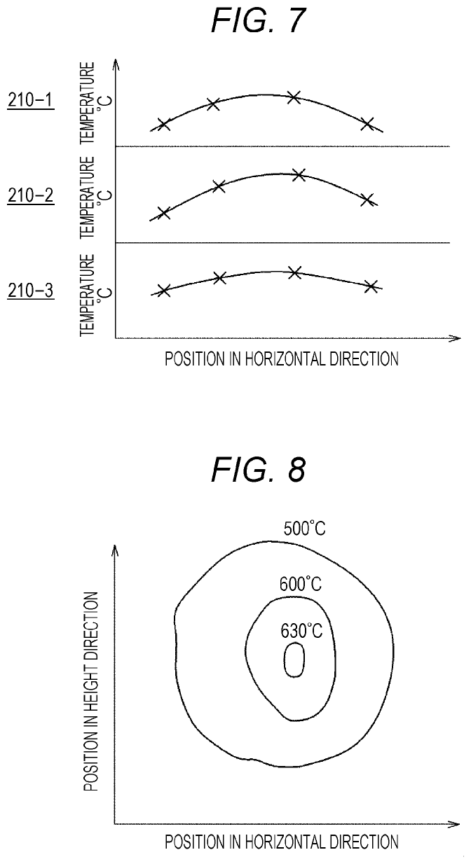

The graph of FIG. 7 indicates a distribution of temperatures measured by the temperature sensors 211 attached to the inside of the three tubes 210-1 to 210-3 illustrated in FIG. 4. In the graph of FIG. 7, results of measuring the temperatures at four positions on the substrates while the positions of the tubes 210-1 to 210-3 in the axial direction are shifted are indicated. Here, if the four temperature sensors 211 are attached to the inside of each of the tubes 210-1 to 210-3, the data as indicated in FIG. 7 can be obtained even if the temperatures at the four positions are simultaneously measured without shifting the axial positions of the tubes 210-1 to 210-3.

The temperatures are measured by each temperature sensor 211 of the first temperature measurer 200 simultaneously with the temperature sensors 191, 192 and 193 of the second temperature measurer 190. As a result, a relationship between the temperatures measured by the temperature sensors 191, 192 and 193 of the second temperature measurer 190 and the temperatures at the four positions sequentially measured by one temperature sensor 211 while each of the positions of the tubes 210-1 to 210-3 of the first temperature measurer 200 is shifted, or the temperatures simultaneously measured by four temperature sensors 211 mounted inside the tubes 210-1 to 210-3 is obtained.

Such temperature measurement is performed by changing a heating condition inside the inner tube 130 including the reaction tube 120 by changing a voltage to be applied to each of the zone heaters 111, 112 and 113 of the heater 110, whereby the heating condition, the temperature measurement results by each temperature sensor 211 of the first temperature measurer 200 under the plurality of heating conditions, and data of the temperature measurement results by the temperature sensors 191, 192 and 193 of the second temperature measurer 190 are stored in a memory 180c described later in association with each other.

The graph of FIG. 8 indicates a temperature distribution in a horizontal direction and a height direction (vertical direction) inside the inner tube 130 obtained from the graph of FIG. 7. In this manner, the temperature distribution in the height direction inside the inner tube 130 can be obtained by measuring the temperatures at a plurality of positions in the horizontal direction at a plurality of positions having different heights. This makes it possible to perform more accurate temperature control inside the inner tube 130.

### [Controller]

FIG. 9 illustrates a configuration of the controller 180 which is a controller of the substrate processing apparatus 100 according to the present embodiment. The controller 180 is configured as a computer including a central processing unit (CPU) 180a, a random access memory (RAM) 180b, a memory 180c, and an input/output port (I/O port) 180d. The RAM 180b, the memory 180c, and the I/O port 180d are configured to be able to exchange data with the CPU 180a via an internal bus 180e. An input/output device 181 configured as, for example, a touch panel, or the like, and an external memory 182 are configured to be connectable to the controller 180.

The memory 180c includes a storage medium such as a flash memory or a hard disk drive (HDD). In the memory 180c, a control program for controlling operation of the substrate processing apparatus 100, a process recipe in which procedures and conditions of substrate processing to be described later are described, and a database in which the heating conditions described above are associated with data of the temperature measurement results by the first temperature measurer 200 and the temperature measurement results by the second temperature measurer 190 under the plurality of heating conditions, and the like, are stored in a readable manner.

The process recipe is a combination of procedures in a substrate processing process to be described later so that the controller 180 can execute the procedures to obtain a predetermined result, and functions as a program.

Hereinafter, the process recipe and the control program will be also collectively and simply referred to as a program. Furthermore, in the present specification, in some cases, the term “program” indicates only the process recipe, only the control program, or both of the process recipe and the control program.

In addition, the RAM 180b is configured as a memory area (work area) in which the program, data, and the like, read by the CPU 180a are temporarily stored.

The I/O port 180d is connected to the heater 110, the vertical drive motor 162 of the boat elevator 160, the rotary drive motor 161, a substrate carry-in port (not illustrated), a mass flow controller, a vacuum pump, and the like.

The expression “connection” in the present disclosure not only means that each component is connected through a physical cable but also means that a signal (electronic data) in each component is transmittable/receivable directly or indirectly. For example, a signal relay, a signal converter, or a signal computing unit may be provided between respective components.

The CPU 180a is configured to read and execute a control program from the memory 180c and to read the process recipe from the memory 180c in response to input of an operation command from the controller 180, or the like. Then, the CPU 180a is configured to be capable of controlling power supply operation to the heater 110, rotation operation of the vertical drive motor 162 and the rotary drive motor 161 of the boat elevator 160, opening/closing operation of the substrate carry-in port (not illustrated), and the like, according to content of the read process recipe.

The controller 180 is not limited to being configured as a dedicated computer and may be configured as a general-purpose computer. For example, the controller 180 according to the present embodiment can be configured by preparing an external memory (for example, a magnetic tape, a magnetic disk such as a flexible disk or a hard disk, an optical disk such as a CD or a DVD, a magneto-optical disk such as an MO, or a semiconductor memory such as a USB memory or a memory card) 182 storing the above-described program and installing the program in a general-purpose computer using the external memory 182.

Means for supplying the program to the computer is not limited to a case of supplying the program via the external memory 182. For example, the program may be provided through a network 183 (e.g., the Internet or a dedicated line), instead of through the external memory 182. Furthermore, the memory 180c and the external memory 182 are configured as computer-readable recording media. Hereinafter, these are also collectively and simply referred to as a recording medium. In the present specification, in some cases, the term “recording medium” indicates only the memory 180c, only the external memory 182, or both thereof.

### [Substrate Processing Process (Film Formation Process)]

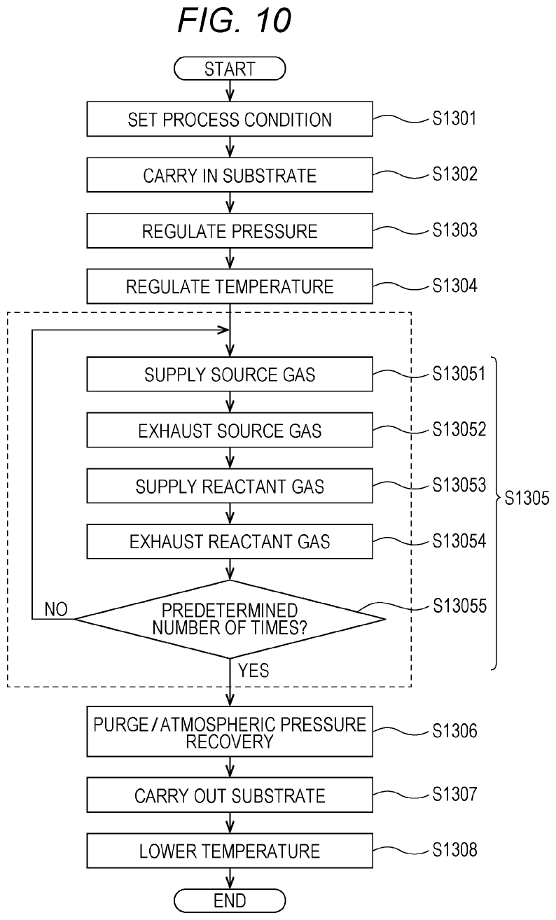

Next, a substrate processing process (film formation process) in which a film is formed onto the substrate 101 with the substrate processing apparatus 100 described with FIGS. 1 and 9 will be described with FIG. 10.

Although the present disclosure can be applied to both a film formation process and an etching process, a process of forming a SiO₂ (silicon oxide) layer as an example of a process of forming a thin film on the substrate 101 will be described as one process of a manufacturing process of a semiconductor device (device). The process of forming a film such as a SiO₂ layer is executed inside the reaction tube 120 of the substrate processing apparatus 100 described above. The manufacturing process is executed by executing a program stored in the memory 180c of the controller 180.

In the substrate processing process (manufacturing process of the semiconductor device) according to the present embodiment, first, retreat of the tubes 210-1 to 210-3 of the first temperature measurer 200 to the positions illustrated in FIG. 1 is detected by a position detector (not illustrated), and in response to a signal of the position detector, the vertical drive motor 162 of the boat elevator 160 is operated to raise the substrate support (boat) 140. As a result, in the boat elevator 160, the substrate support 140 is inserted into the inner tube 130 installed inside the reaction tube 120 as illustrated in FIG. 1. In this state, the substrates 101 placed on the substrate support 140 have a predetermined height (interval) with respect to the partition plates 142.

In this state,
(a) while power is applied to each of the zone heaters 111, 112 and 113 of the heater 110 to heat the plurality of substrates 101 held by the substrate support 140 inserted into the inner tube 130, the first temperature measurer 200 measures a temperature in the vicinity of the substrates 101 and the second temperature measurer 190 measures a temperature of a lateral portion of the reaction tube 120, and the rotary drive motor 161 of the boat elevator 160 is operated to rotate the substrate support 140 at a constant speed.

The process includes:
(b) supplying a first gas from the introduction tube 153 of the gas supplier 150 to the inside of the inner tube 130 with respect to the substrates 101 accommodated in the inner tube 130;
(c) stopping the introduction of the first gas from the introduction tube 153 and discharging a residual gas inside the reaction tube 120 to the outside from the exhauster 261 to remove the residual gas;
(d) supplying a second gas from the introduction tube 153 to the inside of the inner tube 130 with respect to the substrates 101 accommodated in the inner tube 130; and
(e) stopping introduction of the gas from the introduction tube 153 and discharging a residual gas inside the reaction tube 120 from the exhauster 261 to the outside to remove the residual gas, and the above-described (b) to (e) are repeated a plurality of times to form a first layer on the substrates 101.

Note that, in the present specification, in some cases, the term “substrate” means “a substrate itself” or means “a laminate (aggregate) of a substrate and a predetermined layer or film formed on the surface of the substrate” (that is, a substrate and a predetermined layer or film formed on the surface of the substrate are collectively referred to as a substrate). In the present specification, in some cases, the term “surface of a substrate” means “the surface (exposed face) of a substrate itself” or means “the surface of a predetermined layer or film formed on a substrate, namely, the outermost surface of a substrate serving as a laminate”. Furthermore, in the present specification, the term “wafer” is synonymous with the term “substrate”.

Next, an example of a specific film formation process will be described along a flowchart illustrated in FIG. 10.

### (Process Condition Setting): S1301

First, the CPU 180a of the controller 180 reads the process recipe and a related database stored in the memory 180c and sets a process condition.

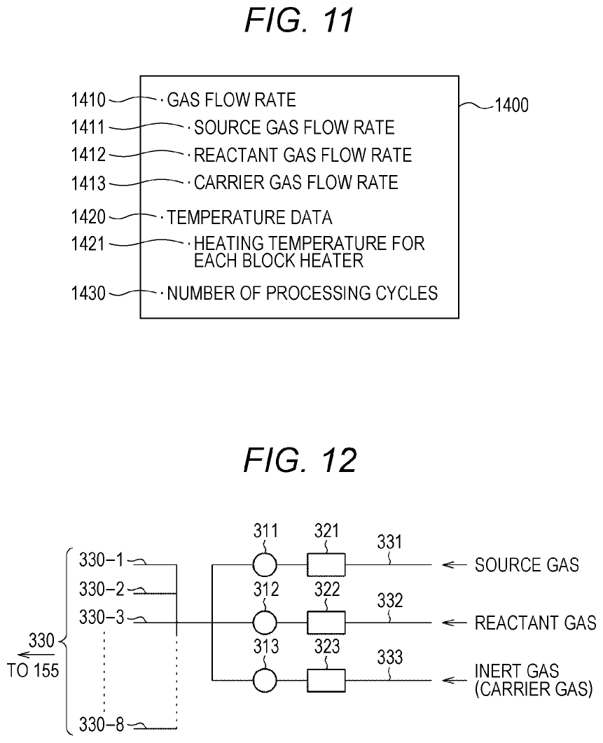

FIG. 11 illustrates an example of a process recipe 1400 to be read by the CPU 180a. Main items of the process recipe 1400 include a gas flow rate 1410, temperature data 1420, the number of processing cycles 1430, and the like.

The gas flow rate 1410 includes items such as a source material gas flow rate 1411, a reactant gas flow rate 1412, and a carrier gas flow rate 1413 to be supplied from a gas supply source (not illustrated) to the inside of the reaction tube 120 and the inner tube 130 through the introduction tube 153 of the gas supplier 150.

The temperature data 1420 includes a heating temperature 1421 (applied voltage for each of the zone heaters 111, 112 and 113) for each of the zone heaters 111, 112 and 113 of the heater 110 based on a relationship between the temperatures measured by the temperature sensors 191, 192 and 193 of the second temperature measurer 190 obtained in advance and the temperatures measured by the temperature sensors 211 mounted inside the tubes 210-1 to 210-3 as the first temperature measurer 200.

### (Carry-In of Substrate): S1302

In a state where new substrates 101 are mounted and held one by one on the substrate support 140, the vertical drive motor 162 of the boat elevator 160 is driven to raise the substrate support 140, and the substrate support 140 is carried into the inner tube 130 installed inside the reaction tube 120.

### (Pressure Regulation): S1303

In a state where the substrate support 140 is carried into the inner tube 130, a pressure inside the reaction tube 120 is regulated to be a desired pressure by vacuum-exhausting the inside of the reaction tube 120 from the exhauster 261 by a vacuum pump (not illustrated).

### (Temperature Regulation): S1304

On the basis of the process recipe read in step S1301, the inside of the reaction tube 120 is heated by the heater 110 in a state where the inside of the reaction tube 120 is vacuum-exhausted by a vacuum pump (not illustrated) so as to have a desired pressure (degree of vacuum). In this event, using temperature information measured by the temperature sensors 211 mounted inside the tubes 210-1 to 210-3 that are the first temperature measurer 200 and the temperature sensors 191, 192 and 193 that are the second temperature measurer 190, the CPU 180a estimates a plurality of temperature distributions in the vicinity of the surfaces of the substrates 101 on the basis of a relationship between temperature distribution data at a plurality of positions in the vicinity of the surfaces of the substrates 101 inside the inner tube 130 measured in advance with the configuration as illustrated in FIG. 6 and the temperatures measured by the temperature sensors 211 mounted inside the tubes 210-1 to 210-3 that are the first temperature measurer 200 at that time and the temperatures measured by the temperature sensors 191, 192 and 193 that are the second temperature measurer 190 at the lateral portion of the reaction tube 120 and feedback controls a power supply amount (applied voltage) for each of the zone heaters 111, 112 and 113 of the heater 110 so that the temperatures measured by the temperature sensors 211 mounted inside the tubes 210-1 to 210-3 that are the first temperature measurer 200 become a desired temperature distribution. This temperature control is continuously performed at least until processing on the substrates 101 is completed.

In addition, rotation speed of the substrate support 140 is adjusted by controlling operation of the rotary drive motor 161 of the boat elevator 160 using the temperature information measured by the temperature sensors 211 that are the first temperature measurer 200 and the temperature sensors 191, 192 and 193 that are the second temperature measurer 190.

In other words, on the basis of the relationship between the temperature distribution data at a plurality of positions in the vicinity of the surfaces of the substrates 101 inside the inner tube 130 measured in advance by the first temperature measurer 200 with the configuration illustrated in FIG. 6 and the temperatures measured by the temperature sensors 191, 192 and 193 that are the second temperature measurer 190 at that time, the CPU 180a predicts the temperatures at the plurality of positions in the vicinity of the surfaces of the substrates 101 using the temperature data measured by the temperature sensors 191, 192 and 193 that are the second temperature measurer 190.

In a case where the predicted temperatures are higher than a preset temperature, operation of the rotary drive motor 161 is controlled to increase the rotation speed of the substrate support 140 to be higher than preset rotation speed. On the other hand, in a case where the predicted temperatures are lower than the preset temperature, the operation of the rotary drive motor 161 is controlled to lower the rotation speed of the substrate support 140 than the preset rotation speed.

### [Predetermined Layer Forming Process]: S1305

Subsequently, in order to form the first layer, the following detailed processes are executed.

### (Source Gas Supply): S13051

In a state where the rotation speed of the substrate support 140 holding the substrates 101 is maintained at the preset speed by controlling the operation of the rotary drive motor 161, the source gas serving as the first gas flows from the introduction tube 153 of the gas supplier 150 into the reaction tube 120 in a state where the flow rate is adjusted. The source gas supplied to the reaction tube 120 is supplied to the inside of the inner tube 130 through the gas introduction holes 131 formed in the inner tube 130, and part thereof is not supplied to the inside of the inner tube 130 and remains in the space between the inner tube 130 and the reaction tube 120. Of the source gas supplied from the introduction tube 153, the gas that has not contributed to reaction on the surfaces of the substrates 101 flows out from the slits 132 formed in the inner tube 130 to the side of the reaction tube 120 and is exhausted from the exhauster 261.

By introducing the first gas from the introduction tube 153 to inside of the inner tube 130, the first gas is supplied to the substrates 101 held by the substrate support 140. For example, the flow rate of the source gas for supply is set in a range of 0.002 to 1 standard liter per minute (slm), more preferably, in a range of 0.1 to 1 slm.

In this event, together with the first gas, an inert gas serving as a carrier gas is supplied from the introduction tube 153 to the inside of the reaction tube 120 and is exhausted from the exhauster 261. Specifically, the flow rate of the carrier gas is set in a range of 0.01 to 5 slm, more preferably, in a range of 0.5 to 5 slm.

The carrier gas is supplied from the introduction tube 153 to the inside of the reaction tube 120, and part of the carrier gas enters the inside of the inner tube 130 through the gas introduction holes 131 formed in the inner tube 130. On the other hand, most of the carrier gas supplied into the reaction tube 120 is exhausted from between the reaction tube 120 and the inner tube 130 through the exhauster 261. In this event, the temperature of each of the zone heaters 111, 112 and 113 of the heater 110 is set to such a temperature that the temperatures of the substrates 101 arranged in the vertical direction supported by the substrate support 140 are in a range of, for example, 250 to 550° C. over the entire surface of each substrate 101.

The gas flowing into the inner tube 130 corresponds to the first gas and the carrier gas. By supply of the first gas into the inner tube 130, a first layer, for example, having a thickness of less than that of a mono atomic layer or not more than that of a few atomic layers, is formed on each substrate 101 (on an underlying film of the surface).

### (Source Gas Exhaust): S13052

The first gas that is a source gas is supplied to the inside of the inner tube 130 through the introduction tube 153 for a predetermined period, and supply of the first gas is stopped after the first layer is formed on the surfaces of the substrates 101 heated to a predetermined temperature range. In this event, the inside of the reaction tube 120 is vacuum-exhausted by a vacuum pump (not illustrated), and the unreacted first gas remaining in the reaction tube 120 including the inner tube 130 or the first gas after contributing to formation of the first layer is removed from the inside of the inner tube 130 and the reaction tube 120.

In this event, supply of the carrier gas from the introduction tube 153 to the inside of the reaction tube 120 is maintained. The carrier gas acts as a purge gas, and it is possible to enhance an effect of excluding the unreacted first gas remaining in the reaction tube 120 or the first gas after contributing to formation of the first layer from the inner tube 130 and the reaction tube 120.

### (Reactant Gas Supply): S13053

After removing the residual gas inside the inner tube 130 and the reaction tube 120, the second gas that is the reactant gas is supplied from the introduction tube 153 to the inside of the inner tube 130, and the second gas that has not contributed to reaction is exhausted from the inner tube 130 and the reaction tube 120 via the exhauster 261. As a result, the second gas is supplied to the substrates 101. Specifically, the flow rate of an O₂ gas to be supplied is set in a range of 0.2 to 10 slm, more preferably in a range of 1 to 5 slm.

In this event, in a state where supply of the carrier gas from the introduction tube 153 is stopped and supply of the carrier gas to the inside of the inner tube 130 and the reaction tube 120 is stopped, the carrier gas is prevented from being supplied to the inside of the reaction tube 120 together with the second gas. In other words, the second gas is supplied to the inside of the reaction tube 120 and the inner tube 130 without being diluted with the carrier gas, so that it is possible to improve a film formation rate of the layer to be formed. In this case, a temperature of the heater 110 is set so as to be similar to that in the second gas supply process.

In this event, the gas flowing into the reaction tube 120 and the inner tube 130 is only the second gas. The second gas undergoes substitution reaction with at least part of the first layer formed on the substrates 101 in the source gas supply step (S13051). At the time of the substitution reaction, for example, Si contained in the first layer and O contained in the second gas are bonded to form an SiO₂ layer serving as the second layer containing Si and O on the substrates 101.

### (Residual Gas Exhaust): S13054

After the second layer is formed, supply of the second gas from the introduction tube 153 to the inside of the reaction tube 120 and the inside of the inner tube 130 is stopped. Then, the second gas and the reaction by-products remaining in the reaction tube 120 and the inner tube 130 and remaining unreacted or after contributing to formation of the second layer are removed from the inside of the reaction tube 120 and the inner tube 130 by processing procedure similar to that in step S13052.

### (Implementation of Predetermined Number of Times)

A cycle in which the detailed steps S13051 to S13055 in step S1305 are performed in sequence is carried out one or more times (predetermined number of times (n times) to form, on each substrate 101, the second layer having a predetermined thickness (e.g., 0.1 to 2 nm). The above-described cycle is preferably repeated a plurality of times, for example, preferably performed about 10 to 80 times, and more preferably performed about 10 to 15 times, whereby a thin film having a uniform film thickness distribution can be formed on the surfaces of the substrates 101.

Using temperature information measured by the temperature sensors 191, 192 and 193 of the first temperature measurer 200 and the second temperature measurer 190, the CPU 180a estimates the temperatures at a plurality of positions in the vicinity of the surfaces of the substrates 101 on the basis of a relationship between the temperature distribution data at the plurality of positions in the vicinity of the surfaces of the substrates 101 inside the inner tube 130 measured in advance using the first temperature measurer 200 and the temperatures measured by the temperature sensors 191, 192 and 193 of the second temperature measurer 190 at that time and feedback controls a power supply amount (applied voltage) of the heater 110 for each of the zone heaters 111, 112 and 113 on the basis of the estimated temperature data so that the inside of the reaction tube 120 has a desired temperature distribution from start of the source gas supply to the end of the residual gas exhaust by the reactant gas described above.

In addition, the rotation speed of the substrate support 140 is adjusted by controlling operation of the rotary drive motor 161 of the boat elevator 160 using the temperature information measured by the temperature sensors 191, 192 and 193 of the second temperature measurer 190.

### (After-Purge): S1306

After the series of steps in step S1305 is repeatedly performed a predetermined number of times, an N₂ gas is supplied from the introduction tube 153 to the inside of the reaction tube 120 and the inside of the inner tube 130 and is exhausted from the exhauster 261. The N₂ gas acts as a purge gas, whereby the inside of the reaction tube 120 and the inside of the inner tube 130 are purged with an inert gas, and the gas and by-products remaining in the inside of the reaction tube 120 and the inside of the inner tube 130 are removed from the inside of the reaction tube 120. In addition, heating by the heater 110 is stopped by stopping application of power to each of the blocked zone heaters 111, 112 and 113 of the heater 110, the operation of the rotary drive motor 161 of the boat elevator 160 is stopped, and rotation of the substrate support 140 is stopped.

### (Carry-Out of Substrate): S1307

Thereafter, the vertical drive motor 162 of the boat elevator 160 is operated to lower the substrate support (boat) 140 from the inner tube 130 of the reaction tube 120, and the substrates 101 having a thin film of a predetermined thickness formed on the surface thereof are taken out from the substrate support 140.

### (Temperature Drop): S1308

Finally, the temperature of the heater 110 is lowered in a state where application of power to each of the zone heaters 111, 112 and 113 of the heater 110 is stopped, thereby ending the processing of the substrates 101.

Note that, for example, Si₂Cl₆ (disilicon hexachloride) is used as the first gas (silicon-containing gas), O₂ (oxygen) (or O₃ (ozone) or H₂ O (water)) is used as the second gas (oxygen-containing gas), and an N₂ (nitrogen) gas, an Ar (argon) gas, or the like, is used as the carrier gas (inert gas).

In the example described above, for example, an example in which the SiO₂ film is formed on the substrates 101 has been described, but the present embodiment is not limited thereto. For example, a Si₃N ₄ (silicon nitride) film or a TiN (titanium nitride) film can be formed instead of the SiO₂ film. Further, a film to be formed is not limited to such films. For example, a single-element film of W, Ta, Ru, Mo, Zr, Hf, Al, Si, Ge, Ga, or an element homologous with those elements, a compound film of nitrogen and any of the elements (nitride film), or a compound film of oxygen and any of the elements (oxide film) can alternatively be formed. When these films are formed, the above-described halogen-containing gas or a gas containing at least any of the element of halogen, an amino group, a cyclopenta group, oxygen (O), carbon (C), and an alkyl group can be used.

According to the present disclosure, a substrate temperature during film formation can be maintained at a desired temperature substantially uniformly over the entire surface of each of the plurality of substrates, so that it is possible to stably perform uniform film formation processing on the surfaces of the plurality of wafers arranged at predetermined intervals in the vertical direction inside the reaction tube.

Furthermore, according to the present disclosure, it is possible to achieve both uniform film formation processing on a plurality of wafers loaded on a boat and feedback control of a heater on the basis of a temperature measurement result of a thermocouple for measuring a temperature of a process chamber, so that it is possible to provide a substrate processing apparatus capable of performing uniform film formation processing on surfaces of a plurality of wafers arranged at predetermined intervals in a vertical direction inside a reaction tube.

According to the present disclosure described above, the temperature can be controlled for each block heater during film formation on the substrates on the basis of data measured in advance, so that the temperatures of the substrates being processed can be substantially uniformly maintained, so that it is possible to stably maintain formation of a high-quality thin film on the surface of each of a large number of aligned substrates.

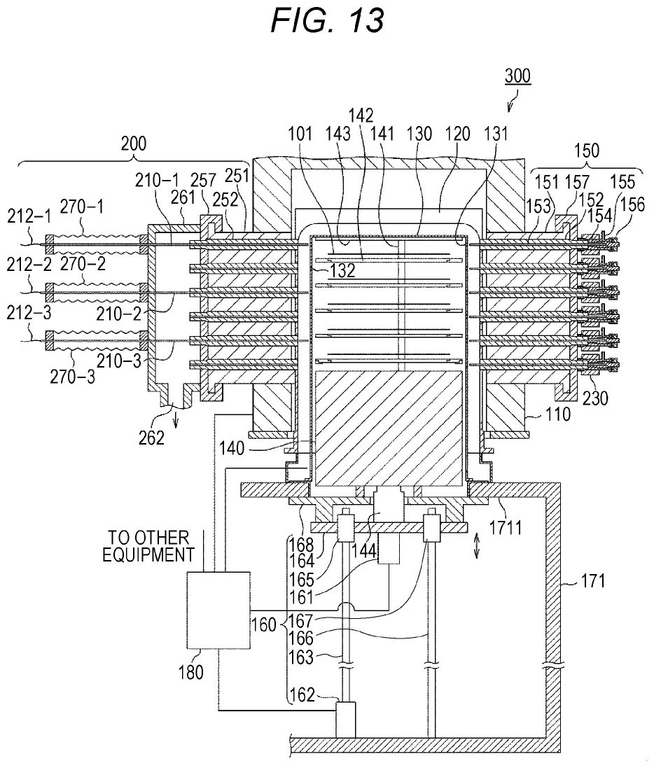

As a substrate processing apparatus 300 according to a second embodiment of the present disclosure, a configuration in which a heater 230 is attached to the side of the protrusion cover 157 in a gas introducer 154 of the gas supplier 150 in the configuration of FIG. 1 as the substrate processing apparatus 100 described in the first embodiment will be described with reference to FIG. 13. The same components as those in the configuration of FIG. 1 described in the first embodiment will be denoted by the same component number to avoid redundant description.

In a case where the temperature inside the reaction tube 120 measured by the second temperature measurer 190 fixed inside the reaction tube 120 is lower than the preset temperature, in the first embodiment, power is applied to each of the zone heaters 111, 112 and 113 constituting the heater 110 to heat the substrates 101 held by the substrate support (boat) 140 inside the inner tube 130.

However, in a case where the temperature of each of the zone heaters 111, 112 and 113 constituting the heater 110 greatly deviates from the predetermined temperature for some reason, or the like, even if the power applied to each of the zone heaters 111, 112 and 113 is increased, there is a case where the temperature of each of the zone heaters 111, 112 and 113 may not immediately follow the increase.

On the other hand, in the present embodiment, the heater 230 is attached to the protrusion cover 157 side of the gas introducer 154, and the gas is heated inside holes 1531 formed in the introduction tube 153 by the heater 230 before being supplied into the reaction tube 120.

In other words, in a case where the temperature inside the reaction tube 120 corresponding to the position of each of the zone heaters 111, 112 and 113 constituting the heater 110 measured by the second temperature measurer 190 fixed inside the reaction tube 120 is lower than the preset temperature, power is applied to each of the zone heaters 111, 112 and 113 constituting the heater 110 to heat the substrates 101 held by the substrate support (boat) 140 inside the inner tube 130, and at the same time, power is applied to the heater 230 attached to the side of the protrusion cover 157 of the gas introducer 154 to heat the gas introducer 154 and the introduction tube 153 inserted into the gas introducer 154, and the gas to be supplied into the reaction tube 120 through the inside of the holes 1531 of the introduction tube 153 is heated.

With such a configuration, it is possible to quickly cope with fluctuation in the temperature inside the reaction tube 120 measured by the second temperature measurer 190, so that it is possible to keep quality of the film formed on the substrates 101 constant.

In addition, with the configuration in which the heater 230 is attached to the side of the protrusion cover 157 of the gas introducer 154, the gas to be supplied into the reaction tube 120 can be preheated by the heater 230, a difference between the temperature of the gas immediately after being introduced into the inner tube 130 and the temperature of the gas staying in the inner tube 130 is reduced, so that it is possible to keep quality of the film formed on the substrates 101 constant.

According to the present embodiment described above, the temperature can be controlled for each block heater during film formation on the substrates on the basis of data measured in advance, and thus, the temperatures of the substrates being processed can be substantially uniformly maintained, so that it is possible to stably maintain formation of a high-quality thin film on each surface of a large number of aligned substrates.

In the above embodiments, an example in which a plurality of storages is provided has been described, but the present disclosure is not limited thereto, and one storage may be provided.

In the above embodiments, the configuration in which the plurality of substrates is held by a substrate holder has been described, but the present disclosure is not limited thereto, and one substrate may be held by the substrate holder and processed, or the substrate holder may be configured to be able to hold one substrate.

Further, in the above embodiments, the film formation process is described as one process of the manufacturing process of the semiconductor device, but the manufacturing process is not limited to the film formation process, and processes such as heat treatment and plasma treatment can be also applied.

Still further, in the above embodiments, the substrate processing apparatus capable of performing one process of the manufacturing process of the semiconductor device has been described, but the present disclosure is not limited thereto, and the substrate processing apparatus may be a substrate processing apparatus that processes substrates such as a ceramic substrate, a substrate of a liquid crystal device, and a substrate of a light emitting device.

According to the present disclosure, it is possible to further improve processing uniformity of substrates.

What is claimed is:

1. A substrate processing apparatus comprising:
a reaction chamber that accommodates a substrate held by a substrate holder;
a heater disposed around the reaction chamber; and
an exhauster disposed laterally to the reaction chamber and configured to accommodate a first temperature measurer disposed extending in a direction parallel to a surface of the substrate held by the substrate holder from an outside of the reaction chamber toward an inside of the reaction chamber.

2. The substrate processing apparatus according to claim 1, wherein the first temperature measurer includes a tube incorporating a temperature sensor.

3. The substrate processing apparatus according to claim 2, wherein the tube is disposed to be slidable back and forth with respect to the exhauster.

4. The substrate processing apparatus according to claim 1, wherein the substrate holder is configured to hold a plurality of substrates.

5. The substrate processing apparatus according to claim 4, wherein the first temperature measurer is positioned between the plurality of substrates held by the substrate holder.

6. The substrate processing apparatus according to claim 1, wherein the heater includes a plurality of zone heaters corresponding to different positions in a height direction of the reaction chamber.

7. The substrate processing apparatus according to claim 6, wherein
the first temperature measurer is disposed at a position corresponding to a height of each of the plurality of zone heaters.

8. The substrate processing apparatus according to claim 7, further comprising
a second temperature measurer that is fixed inside the reaction chamber and is configured to measure a temperature inside the reaction chamber.

9. The substrate processing apparatus according to claim 8, wherein
the second temperature measurer includes a plurality of temperature sensors at positions corresponding to respective heights of the plurality of zone heaters.

10. The substrate processing apparatus according to claim 6, wherein
the first temperature measurer includes a plurality of tubes incorporating a plurality of temperature sensors, and
the plurality of tubes is disposed at positions corresponding to respective heights of the plurality of zone heaters of the exhauster.

11. The substrate processing apparatus according to claim 10, wherein
the first temperature measurer simultaneously measures temperatures at a plurality of positions corresponding to the plurality of zone heaters by the plurality of temperature sensors incorporated in the tubes.

12. The substrate processing apparatus according to claim 10, comprising a controller, wherein the controller is configured to control the plurality of zone heaters on a basis of data of temperature distributions at a plurality of points at the positions corresponding to the plurality of zone heaters measured by the first temperature measurer.

13. The substrate processing apparatus according to claim 1, wherein the first temperature measurer is disposed at a position where temperature of the substrate is measured during processing of the substrates.

14. The substrate processing apparatus according to claim 13, wherein the first temperature measurer is disposed between the substrate and the exhauster.

15. The substrate processing apparatus according to claim 14, comprising
a position adjuster configured to adjust a position of the first temperature measurer,
wherein the position adjuster is configured to dispose the first temperature measurer between the substrate and the exhauster.

16. A method of processing a substrate comprising:
accommodating a substrate holder in a reaction chamber;
heating the reaction chamber;
inserting a first temperature measurer, which is located in an exhauster laterally to the reaction chamber, into the reaction chamber, and measuring a temperature of a substrate held by the substrate holder by the first temperature measurer;
adjusting a position of the first temperature measurer to a position near the substrate;
supplying a gas into the reaction chamber; and
heating and processing the substrate on a basis of the temperature of the substrate measured by the first temperature measurer.

17. A method of processing a substrate according to claim 16, whereby the substrate comprises a semiconductor device comprising.

18. A non-transitory computer-readable recording medium storing a program that causes, by a computer, a substrate processing apparatus to perform:
accommodating a substrate holder in a reaction chamber;
heating the reaction chamber;
inserting a first temperature measurer, which is located in an exhauster laterally to the reaction chamber, into the reaction chamber, and causing the first temperature measurer to measure a temperature of a substrate held by the substrate holder;
adjusting a position of the first temperature measurer to a position near the substrate;
supplying a gas into the reaction chamber; and
heating and processing the substrate on a basis of a result of measuring the temperature of the substrate by the first temperature measurer.
